(19) United States
(12) Patent Application Publication
(10) Pub. No.: US 2006/0105247 A1
(43) Pub. Date: May 18, 2006

(54) Microstructure comprising an adhesive layer and method of fabrication of said microstructure

(75) Inventors: Marc Rabarot, Saint-Egreve (FR); Jacqueline Bablet, Le Gua (FR)

Correspondence Address: OLIFF & BERRIDGE, PLC, P.O. BOX 19928, ALEXANDRIA, VA, 22320, US

(73) Assignee: COMMISSARIAT A L'ENERGIE ATOMIQUE, Paris (FR)

(21) Appl. No.: 10/538,351

(22) PCT Filed: Dec. 18, 2003
(86) PCT No.: PCT/FR03/03788

§ 371 Date: Jun. 10, 2005

(30) Foreign Application Priority Data
Dec. 20, 2002 (FR) 02/16272

(51) Int. Cl. G03F 1/00

(52) U.S. Cl. 430/5

(57) ABSTRACT

The invention concerns a microstructure comprising an adhesive layer between a substrate and a photo-patternable layer, arranged on at least one face of the substrate. The adhesive layer is photosensitive and consists of a negative resin comprising at least one polymer of the family of elastomers and at least one photo-initiating component, in solution in an aromatic solvent. The photo-patternable layer consists of at least one negative epoxy resin. The method of fabrication of such a microstructure comprises spreading and drying the adhesive layer prior to depositing the photo-patternable layer. The adhesive layer can be exposed through a mask and developed, prior to the deposition of the photo-patternable layer.

### BACKGROUND OF THE INVENTION

The invention relates to a microstructure comprising an adhesive layer between a substrate and a photo-patternable layer, the adhesive layer being photosensitive and arranged on at least one face of the substrate.

The invention also relates to a method of fabrication of such a microstructure.

### STATE OF THE PRIOR ART

Microstructures comprising thick layers are generally used either directly, for example as components in micro-mechanics, or indirectly as sacrificial positive structures for making metal micro-moulds. It is known to achieve such microstructures from at least one photosensitive layer of negative resin of epoxy type such as that marketed by Micro-Chemical Corporation under the reference SU-8. This type of photosensitive layer can be implemented by a fabrication method known under the name of LIGA-UV and derived from the LIGA (“Lithographie Galvaniserung Abformung”) process.

The LIGA-UV process consists in depositing a photosensitive resin layer on a substrate. The photosensitive resin layer is dried, then irradiated by ultraviolet (UV) radiation through a mask. It then undergoes annealing and is developed, i.e., for a negative resin, the portions of resin not polymerized by UV irradiation and annealing are eliminated by physical or chemical means. This enables microstructures with a high form factor to be achieved. What is meant by form factor is a critical ratio of the height over the width of a pattern, a pattern corresponding to the space made free by a portion of non-polymerized resin, in the case of use of a negative photosensitive resin.

To give an example, the document EP-A1-0851295 describes a method for making microstructures by multilayer conformation of a negative photosensitive resin of epoxy type. The microstructures are achieved by creating a metal sacrificial layer on a wafer and by structuring at least two layers of negative photosensitive resin. The patterned layers are then detached from the wafer by performing alkaline attack of the sacrificial layer.

The large thickness of the photosensitive resin layers and the geometry of the mask, the dimensions of the microstructure obtained and the nature of the substrate are parameters able to induce large stresses in the substrate. The stresses can be the cause of a decrease of the adherence between the photosensitive layer and the substrate and this may lead to unsticking of the pattern, either directly on completion of the development step or in the subsequent steps of the fabrication cycle.

To avoid such unstickings, certain people have attempted to modify the process parameters, in particular by reducing the annealing temperature and/or irradiation doses. This is not satisfactory as these modifications can increase the process time and do not enable the stresses linked to the geometry of the mask or to the nature of the substrate to be reduced.

Another technique consists in using an intermediate adhesive layer between the photosensitive layer and the substrate. Thus the document W0-A1-0137050 describes an adhesive layer formed by a polymer of the polyimide family or by a mixture of polyimides. However, this polymer is not satisfactory as it has a high polymerization temperature, generally comprised between 250° C. and 400° C. This can be limiting in implementing the method for making the microstructures, in particular with substrates made of plastic material.

### OBJECT OF THE INVENTION

It is an object of the invention to provide a microstructure remedying these shortcomings.

According to the invention, this object is achieved by the fact that the adhesive layer is formed by a negative resin comprising at least one polymer of the elastomer family and at least one photo-initiating component, in solution in an aromatic solvent.

According to a development of the invention, the polymer is a cyclic polyisoprene in solution in xylene.

According to a preferred embodiment, the adhesive layer has a thickness comprised between 200 nm and 10 μm.

According to another feature of the invention, the photo-patternable layer is formed by at least one negative resin of epoxy type.

It is also an object of the invention to achieve a method of fabrication of such a microstructure.

According to the invention, the fabrication method comprises spreading and drying of an adhesive layer formed by a negative resin comprising at least one polymer of the elastomer family and at least one photo-initiating component, in solution in an aromatic solvent, before deposition of at least one photo-patternable resin layer.

According to a development of the invention, the adhesive layer is exposed through a mask and developed, before deposition of the photo-patternable layer.

### BRIEF DESCRIPTION OF THE DRAWINGS

Other advantages and features will become more clearly apparent from the following description of particular embodiments of the invention given as non-restrictive examples only and represented in the accompanying drawings, in which:

FIGS. 1 to 5 and 6 to 9 respectively represent different steps of a first and second embodiments of a microstructure according to the invention.

FIGS. 10 and 11 represent an alternative embodiment of the second embodiment of a microstructure according to the invention.

FIGS. 12 to 13 and 14 to 17 respectively represent different steps of a third and fourth embodiments of a microstructure according to the invention.

### DESCRIPTION OF PARTICULAR EMBODIMENTS

A microstructure, preferably designed to be used as a component in micro-mechanics or as a sacrificial positive structure for making metal micro-moulds, is achieved from at least one photo-patternable layer and a substrate by an LIGA-UV type process. What is meant by photo-patternable layer is a layer sensitive to ultraviolet radiation and designed to be structured to form patterns. The photo-patternable layer is preferably formed by at least one negative resin of epoxy type, and more particularly by the SU-8 resin marketed by Micro-Chemical Corporation. It preferably has a thickness comprised between 50 μm and 200 μm.

An adhesive layer designed to improve the adherence between the substrate and the photo-patternable layer is arranged on at least one face of the substrate and it preferably has a thickness comprised between 200 nm and 10 μm. The adhesive layer is photosensitive, i.e. sensitive to ultraviolet radiation, and it is formed by a negative resin comprising at least one polymer of the elastomer family and at least one photo-initiating component, in solution in an aromatic solvent. The polymer is preferably a cyclic polyisoprene in solution in xylene, and for example selected from the group consisting of photosensitive resins marketed by Olin Microelectronic Materials under the name of SC Resist.

The resin of the adhesive layer presents the advantage of having a polymerization temperature lower than 135° C. and it can absorb the stresses that occur between the substrate and the photo-patternable layer. In addition, its small thickness in particular with respect to the thickness of the photo-patternable layer made of epoxy resin, enable the influence of the geometry of the microstructure and the nature of the substrate to be eliminated.

As the resin belongs to the elastomer family, it can create organo-chemical bonds between epoxy resins and most of the materials forming the substrate. The substrate can thus be formed by a material selected from the group consisting of silicon, glass and plastics, in particular polycarbonate, polymethyl methacrylate (PMMA) or the cyclo-olefine copolymer (COC), depending on the intended applications. The substrate can also be covered by a conducting sub-layer arranged between the substrate and the adhesive layer. The conducting layer is preferably made of metal and in particular of gold, nickel or an alloy of iron and nickel, copper, titanium, chromium or aluminium. The adhesive layer also enables a good adherence to be achieved between the epoxy resin and a conducting sub-layer.

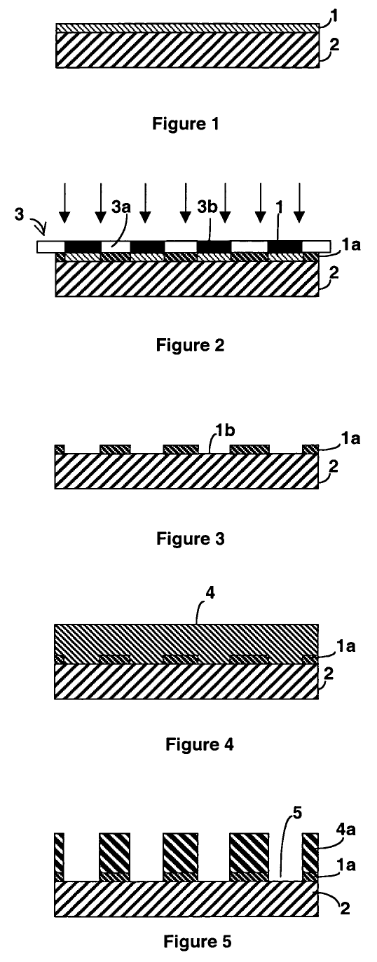

According to a first embodiment represented in FIGS. 1 to 5, a microstructure is achieved by spreading an adhesive layer 1 on a substrate 2 (FIG. 1). The adhesive layer 1 preferably has a thickness of 2.5 μm and is formed by a negative resin comprising at least one polymer of the elastomer family and at least one photo-initiating component, in solution in an aromatic solvent. The adhesive layer 1 is preferably a resin of the SC Resist type.

The adhesive layer 1 is dried for 10 minutes at a temperature comprised between 75° C. and 95° C., and preferably at 85° C. Then it undergoes exposure by ultraviolet radiation (represented by arrows in FIG. 2) through a mask 3. Exposure by ultraviolet radiation is preferably from 200 to 1000 mJ.cm⁻² at a wavelength of 365 nm. The mask 3 comprises a plurality of first and second zones 3a and 3b respectively transparent and opaque to ultraviolet radiation. It thus enables zones 1a of the adhesive layer 1 of negative resin to be locally exposed, said zones 1a being arranged facing first zones 3a of the mask 3.

The adhesive layer 1 then undergoes annealing designed to cause polymerization of the exposed zones 1a of the adhesive layer 1. For example, annealing is performed at a temperature comprised between 90 and 95° C. for 15 to 30 minutes. The adhesive layer 1 is then developed by any type of known means so as to eliminate the non-exposed and non-polymerized zones of the adhesive layer 1 and to reveal patterns 1b (FIG. 3). The adhesive layer 1 can thus be developed in a solvent bath such as propylene glycol methylether acetate, better known under the name of PGMEA, so that the non-exposed zones of the adhesive layer dissolve in the solvent.

A photo-patternable layer 4, made of negative resin of epoxy type and preferably of SU-8 resin, is spread on the revealed adhesive layer and on the substrate 2. It preferably has a thickness of 150 μm and undergoes a treatment of LIGA-UV type similar to that undergone by the adhesive layer 1. Thus, it is dried and exposed by ultraviolet radiation through a mask (not shown in FIGS. 4 and 5). The mask can be identical to or slightly different from the mask 3 used to reveal the adhesive layer 1. In FIG. 5, the mask used is identical to the mask 3 used for the adhesive layer 1, so that the exposed zones 4a of the photo-patternable layer 4 coincide widthwise with the exposed zones 1a of the adhesive layer 1 (FIG. 5). Thus, once the photo-patternable layer 4 has been developed, the patterns revealed by exposure of the photo-patternable layer 4 are superposed on the patterns 1a revealed by exposure of the adhesive layer 1 to form patterns 5 exposing the substrate 2.

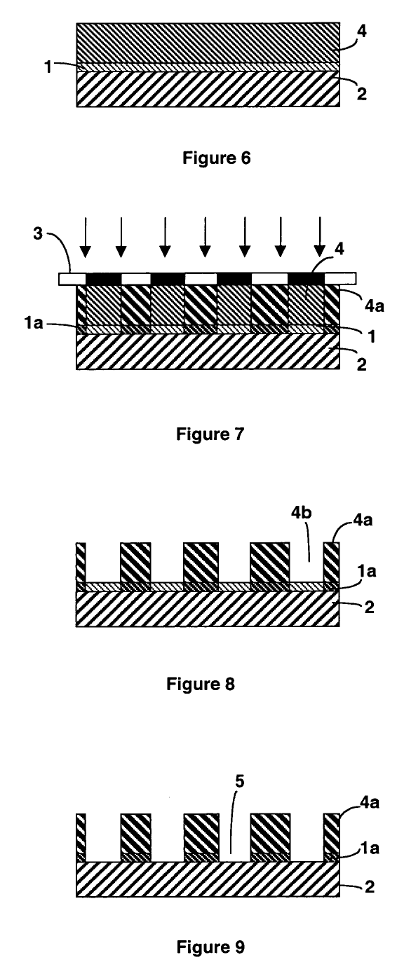

According to a second embodiment represented in FIGS. 6 to 9, the adhesive layer 1 and the photo-patternable layer 4 are successively spread on the substrate 1 and dried (FIG. 6). The photo-patternable layer 4 is then locally exposed by ultraviolet radiation (represented by arrows in FIG. 7) through the mask 3. The photo-patternable layer 4 then undergoes annealing designed to polymerize the exposed zones 4a. It is then specifically developed so as to reveal patterns 4b caused by elimination of the non-exposed zones of the photo-patternable layer 4 (FIG. 8).

As the adhesive layer is made of negative photosensitive resin, exposure by ultraviolet radiation causes not only localized reticulation of the photo-patternable layer 4 but also that of the adhesive layer 1. The adhesive layer 1 can then be specifically developed to reveal patterns coinciding widthwise with the patterns 4b so as to form patterns 5 exposing the substrate 2 (FIG. 9). This embodiment is particularly interesting, in particular in the case where the structure of the substrate (or of the intermediate sub-layer) is not compatible with another structuring method.

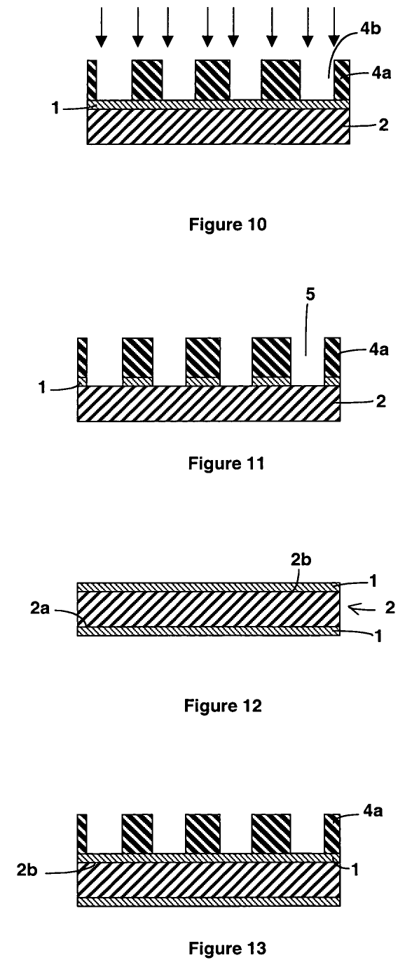

According to an alternative embodiment represented in FIGS. 10 and 11, the adhesive layer 1 and the photo-patternable layer 4 are implemented according to the embodiment represented in FIGS. 6 to 8 so as to reveal the patterns 4b arising from development of the photo-patternable layer 4 (FIG. 10). The adhesive layer 1 is then locally etched by reactive plasma (FIG. 10) so as to reveal patterns superposed on the patterns 4b to form patterns 5 (FIG. 11). The exposed zones 4a of the photo-patternable layer 4 and the patterns 4b then act as mask during etching of the adhesive layer 1.

The adhesive layer 1 between the substrate and the photo-patternable layer more particularly enables a plastic substrate 2 to be used, for example a substrate made of polycarbonate or polymethyl methacrylate (PMMA), with a photo-patternable layer 4 made of epoxy resin. It is not in fact always possible to spread a layer of epoxy type resin such as SU-8 resin directly on a plastic substrate. The solvents used, in particular in SU-8 resin, can be the same as those of the polymers used for the plastic substrate. In this case, when the SU-8 resin is spread and developed, the substrate can undergo chemical attack of the solvents contained in the SU-8 resin or in the development bath. The adhesive layer 1 then enables the plastic substrate to be protected.

Thus, in FIGS. 12 and 13, the adhesive layer 1 is arranged on the bottom face 2a and the top face 2b of the substrate 2, so as to preserve the latter from attacks by the solvents contained in the photo-patternable layer 4 structured according to a LIGA-UV type process, and by those contained in the development bath. According to the intended application, the whole of the adhesive layer 1 can be previously exposed by ultraviolet radiation. This more particularly enables micro-components to be achieved using a plastic substrate.

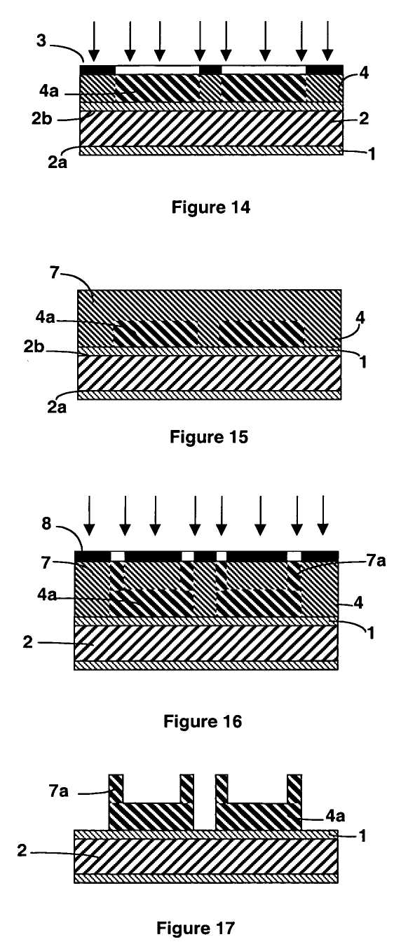

According to another embodiment represented in FIG. 14 to 17, the adhesive layer 1 is arranged and dried on the top face 2b and the bottom face 2a of the substrate 2. A first photo-patternable layer 4 of SU-8 resin is spread on the adhesive layer 1 arranged on the top face 2b of the substrate 2. It is dried, exposed by ultraviolet radiation through a first mask 3 (FIG. 14) then annealed so as to define two polymerized zones 4a. A second photo-patternable layer 7 made of SU-8 resin is spread on the first photo-patternable layer 4 (FIG. 15). The second photo-patternable layer 7 is also dried, exposed through a second mask 8 and annealed so as to define four exposed and polymerized zones 7a.

In the embodiment represented in FIG. 16, the second mask 8 is different from the first mask 3 so as to define in the second photo-patternable layer 7 four exposed zones 7a having a less wide cross-section than the two zones 4a. In FIG. 16, the four zones 7a are therefore arranged, two by two, on a single zone 4a, so as to extend the zones 4a upwards in FIG. 16 and to form a stacked structure in the form of a trough. The first and second photo-patternable layers 4 and 7 are then developed simultaneously so as to eliminate the non-exposed parts of the first and second photo-patternable layers 4 and 7 and to free the stacked structure (FIG. 17). This enables components or micro-components of complex geometry and, for example, micro-cells to be achieved by rapid prototyping on a substrate made of plastic or glass.

The microstructure and method of fabrication of such a microstructure according to the invention present the advantage of preventing unsticking of the patterns created by the LIGA-UV process. They also enable different natures of substrate to be used, in particular plastic substrates.

The method of fabrication of the microstructure and the microstructure according to the invention are particularly suitable for quick fabrication of microfluidic, bio-technological or micro-optical components or systems and micro-fuel cells. The substrate can also be cut into chips, in particular when the substrate is made of silicon, without causing unsticking of the created patterns.

1-11. (canceled)

12. Microstructure comprising an adhesive layer between a substrate and a photo-patternable layer, the adhesive layer being photosensitive, arranged on at least one face of the substrate and being formed by a negative resin comprising at least one polymer of the elastomer family and at least one photo-initiating component, in solution in an aromatic solvent.

13. Microstructure according to claim 12, wherein the polymer is a cyclic polyisoprene in solution in xylene.

14. Microstructure according to claim 12, wherein the adhesive layer has a thickness comprised between 200 nm and 10 μm.

15. Microstructure according to claim 12, wherein the photo-patternable layer is formed by at least one negative resin of epoxy type.

16. Microstructure according to claim 12, wherein the photo-patternable layer has a thickness comprised between 50 μm and 200 μm.

17. Microstructure according to claim 12, wherein the substrate is formed by a material selected from the group consisting of silicon, glass and plastics.

18. Method of fabrication of a microstructure according to claim 12, comprising spreading and drying of an adhesive layer formed by a negative resin comprising at least one polymer of the elastomer family and at least one photo-initiating component, in solution in an aromatic solvent, before deposition of at least one photo-patternable layer of resin.

19. Fabrication method according to claim 18, wherein the adhesive layer is exposed through a mask and developed, before deposition of the photo-patternable layer.

20. Fabrication method according to claim 18, wherein the adhesive layer and the photo-patternable layer are exposed simultaneously through a mask.

21. Fabrication method according to claim 20, wherein the photo-patternable layer and the adhesive layer are developed successively.

22. Fabrication method according to claim 18, wherein at least two photo-patternable layers are developed simultaneously, after having been successively deposited and exposed through two different masks.
